(19) United States
(12) Patent Application Publication
(10) Pub. No.: US 2026/0136609 A1
(43) Pub. Date: May 14, 2026

(54) SPIN QUBIT ELECTRONIC DEVICE

(71) Applicant: Commissariat à l'Énergie Atomique et aux Énergies Alternatives, Paris (FR)

(72) Inventors: Biel Martinez I Diaz, Grenoble (FR); Jing Li, Grenoble (FR)

(73) Assignee: Commissariat à l'Énergie Atomique et aux Énergies Alternatives, Paris (FR)

(21) Appl. No.: 18/931,413

(22) Filed: Oct. 30, 2024

(30) Foreign Application Priority Data
Nov. 7, 2023 (FR) 2312056

(51) Int. Cl. H10D 48/00; B82Y 10/00; G06N 10/40; H10D 48/01

(52) U.S. Cl. CPC H10D 48/3835; G06N 10/40; H10D 48/021; H10D 48/385; B82Y 10/00

(57) ABSTRACT

An electronic device including: a semiconductor nanowire; at least two separate first control gates, arranged next to each other on the side of a first lateral surface of the nanowire, and configured to each control the electrostatic potential of a quantum dot intended to be formed in the nanowire; at least one second control gate arranged on the side of a second lateral surface, opposite to the first lateral surface, of the nanowire, and configured to control the electrostatic potential of a coupling region intended to be formed between two quantum dots; wherein all the first control gates are arranged on the side of the first lateral surface only, and the or all the second control gates are arranged on the side of the second lateral surface only.

### CROSS REFERENCE TO RELATED APPLICATIONS

This application claims priority to French application number 2312056, filed Nov. 7, 2023. The contents of this application is incorporated by reference in its entirety.

### TECHNICAL FIELD

The present disclosure generally concerns the field of spintronics, of quantum devices, and of quantum computing.

### PRIOR ART

There exist quantum devices comprising qubits based on the forming of quantum dots ensuring the confinement of elementary charges (electrons or holes). The quantum information is, for example, encoded on the spin of these particles. Quantum dots are formed by gates via which electrical confinement potentials are created. These gates enable a local adjustment of the electrostatic potential of the quantum dots, that is, the depth of the potential wells of the quantum dots. It is also necessary to be able to electrically control the tunnel coupling, that is, the height of the tunnel barriers, between neighboring quantum dots.

According to a first configuration, gates controlling the coupling between neighboring quantum dots and gates controlling the potentials of the quantum dots may be formed in a same gate level, next to one another. This first configuration is for example described in Ensar Vahapoglu et al, “Single-electron spin resonance in a nanoelectronic device using a global field” Sci. Adv. vol. 7 Issue 33, Aug. 13, 2021, eabg9158.

A problem encountered with this first configuration is that the presence of all these control gates in a same level requires having, for the gates controlling the potentials in the quantum dots, a pitch, that is, a space between the gates controlling the potentials of two neighboring quantum dots, which is relatively large in order to have the space necessary for the forming of the gates controlling the coupling between neighboring quantum dots.

According to a second configuration, the gates controlling the coupling between neighboring quantum dots may be formed in a gate level different from that of the gates controlling the potentials of the quantum dots. This second configuration is for example described in the paper by T. Bédécarrats et al, “A new FDSOI spin qubit platform with 40 nm effective control pitch,” 2021 IEEE International Electron Devices Meeting (IEDM), San Francisco, CA, USA, 2021, pp. 1-4.

A problem encountered with this second configuration is that the longer distance (for example, a few tens of nanometers) between the level of the gates controlling the coupling between neighboring quantum dots and the semiconductor in which the quantum dots are formed generates a poorer electrostatic control by these gates.

### SUMMARY OF THE INVENTION

There thus exists a need to provide an electronic device which does not exhibit one or more of the previously-described disadvantages.

An embodiment provides a solution to all or part of the disadvantages of known solutions and relates to an electronic device comprising:
a semiconductor nanowire;
at least two separate first control gates, arranged next to each other on the side of a first lateral surface of the semiconductor nanowire, and each configured to control the electrostatic potential of a quantum dot intended to be formed in the semiconductor nanowire;
at least one second control gate arranged on the side of a second lateral surface, opposite to the first lateral surface, of the semiconductor nanowire, and configured to control the electrostatic potential of a coupling region intended to be formed between two quantum dots;

wherein all the first control gates of the electronic device are arranged on the side of the first lateral surface only, and the or all the second control gates of the electronic device are arranged on the side of the second lateral surface only.

According to a specific embodiment, at least a portion of an orthogonal projection of the second control gate in a plane parallel to the first lateral surface of the semiconductor nanowire is arranged between orthogonal projections of the two first control gates in the plane parallel to the first lateral surface of the semiconductor nanowire.

According to a specific embodiment, no portion of the second gate is arranged between the first gates.

According to a specific embodiment, each of the first control gates covers a portion of the first lateral gate of the semiconductor nanowire and/or the second control gate covers a portion of the second lateral surface of the semiconductor nanowire.

According to a specific embodiment, each of the first control gates covers a portion of an upper surface of the semiconductor nanowire which is perpendicular to the first and second lateral surfaces, and/or the second control gate covers a portion of the upper surface of the semiconductor nanowire.

According to a specific embodiment, the portions of the upper surface covered with the first control gates extend from a first upper edge of the semiconductor nanowire formed at the junction of the first lateral surface and of the upper surface, to approximately half the distance separating the first and second lateral surfaces from each other.

According to a specific embodiment, the portions of the upper surface covered with the first control gates extend from a first upper edge of the semiconductor nanowire formed at the junction of the first lateral surface and of the upper surface to a second upper edge of the semiconductor nanowire formed at the junction of the second lateral surface and of the upper surface.

According to a specific embodiment, the portion of the upper surface covered with the second control gate extends from a second upper edge of the semiconductor nanowire formed at the junction of the second lateral surface and of the upper surface to approximately half the distance separating the first and second lateral surfaces from each other.

According to a specific embodiment, the electronic device further comprises a dielectric portion running through the semiconductor nanowire from the upper surface of the semiconductor nanowire to a lower surface of the semiconductor nanowire opposite to the upper surface and arranged:
between the portions of the upper surface of the semiconductor nanowire covered with the first control gates and the portion of the upper surface of the semiconductor nanowire covered with the second control gate, or
between a portion of the upper surface of the semiconductor nanowire arranged between the portions of the upper surface of the semiconductor nanowire covered with the first control gates and the portion of the upper surface of the semiconductor nanowire covered with the second control gate.

According to a specific embodiment:
an upper surface of the second control gate, parallel to the upper surface of the semiconductor nanowire, is arranged in a same first plane as an upper surface of each of the first control gates, or
the upper surface of each of the first control gates is arranged in a first plane located between a second plane in which is arranged the upper surface of the second control gate and a third plane in which is arranged an upper surface of the semiconductor nanowire, which is perpendicular to the first and second lateral surfaces.

According to a specific embodiment, said at least one second control gate has a dimension, measured along an extension direction of the semiconductor nanowire (direction parallel to the first and second lateral surfaces of the nanowire, and which corresponds to the length of the nanowire), smaller than a sum of the dimension of each of the two first control gates also measured along the extension direction of the semiconductor nanowire.

According to a specific embodiment, the electronic device comprises N first control gates and N+1 second control gates, with N an integer greater than or equal to 2.

According to a specific embodiment, a distance between said at least one second control gate and the semiconductor nanowire is shorter than 20 nm, and preferably shorter than 10 nm.

According to a specific embodiment, the at least one second gate is located at a (positive) distance of less than 20 nm from the nanowire and preferably less than 10 nm away from the nanowire.

According to another embodiment, there is provided a method of forming an electronic device, comprising:
forming of at least two separate first control gates, arranged next to each other on the side of a first lateral surface of a semiconductor nanowire, and configured to each control the electrostatic potential of at least one quantum dot intended to be formed in the semiconductor nanowire;
forming of at least one second control gate arranged on the side of a second lateral surface, opposite to the first lateral surface, of the semiconductor nanowire, and configured to control the electrostatic potential of a coupling region intended to be formed between two quantum dots;

and wherein all the first control gates of the electronic device are arranged on the first lateral surface only, and the or all the second control gates of the electronic device are arranged on the side of the second lateral surface only.

According to a specific embodiment, the first and second control gates are formed by the implementation:
of at least one lift-off type deposition of at least one electrically-conductive material, or
of at least one deposition of at least one layer of electrically-conductive material on a substrate including the semiconductor nanowire, followed by at least one etching of the layer of electrically-conductive material through openings made in a mask.

According to a specific embodiment, the method further comprises, after the lift-off type deposition of the electrically-conductive material or after the etching of the layer of electrically-conductive material, the implementation of an additional etching of remaining portions of the electrically-conductive material or of the layer of electrically-conductive material, completing the forming of the first and second control gates.

According to a specific embodiment, the forming of the first and second control gates is implemented in such a way that at least a portion of an orthogonal projection of the second control gate in a plane parallel to the first lateral surface of the semiconductor nanowire is arranged between orthogonal projections of the two first control gates in the plane parallel to the first lateral surface of the semiconductor nanowire.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 and FIG. 2 show a first example of an electronic device according to a specific embodiment;

FIG. 3 shows a specific configuration of the first example of an electronic device according to a specific embodiment;

FIG. 4 and FIG. 5 show a second example of an electronic device according to a specific embodiment;

FIG. 6 shows a specific configuration of the second example of an electronic device according to a specific embodiment;

FIG. 7 shows a third example of an electronic device according to a specific embodiment;

FIG. 8 shows a fourth example of an electronic device according to a specific embodiment;

FIG. 9 shows a fifth example of an electronic device according to a specific embodiment;

FIG. 10 shows simulations of the control of the tunnel coupling between two quantum dots obtained in an electronic device according to a specific embodiment;

FIG. 11, FIG. 12, and FIG. 13 show the steps of a first example of a method of forming an electronic device according to a specific embodiment;

FIG. 14 shows one of the steps of a second example of a method of forming an electronic device according to a specific embodiment;

FIG. 15 shows a sixth example of an electronic device according to a specific embodiment;

FIG. 16 shows a seventh example of an electronic device according to a specific embodiment.

### DESCRIPTION OF EMBODIMENTS

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, “lateral” etc., or orientation qualifiers, such as “horizontal”, “vertical”, etc., reference is made unless otherwise specified to the orientation of the drawings. However, these terms give no information regarding the actual position and orientation of the device during its use.

Unless specified otherwise, the expressions “about”, “approximately”, “substantially”, and “in the order of” signify plus or minus 10%, preferably of plus or minus 5%.

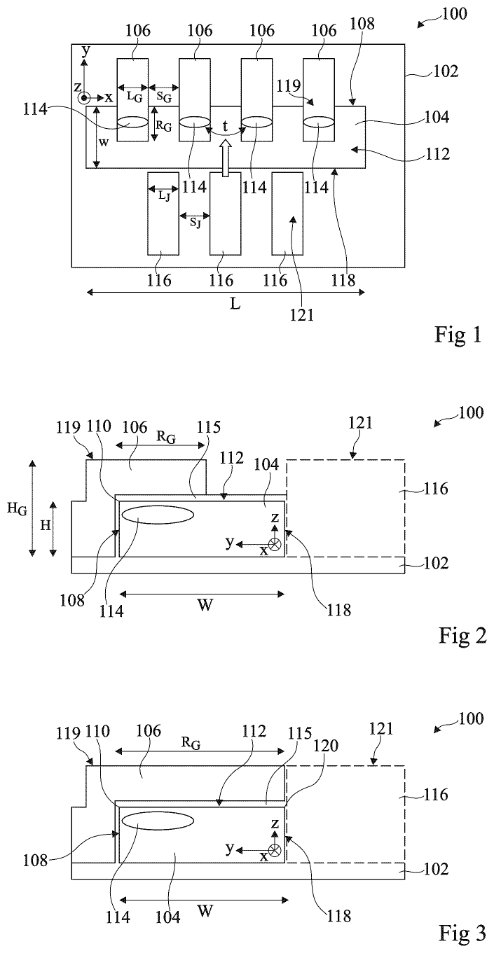

A first example of an electronic device 100 according to a specific embodiment is described hereafter in relation with FIGS. 1 and 2. FIG. 1 is a top view of device 100 and FIG. 2 is a side cross-section view of device 100.

In this first example, as in the next examples of embodiment, device 100 comprises at least one support layer 102 having a semiconductor nanowire 104 arranged thereon. According to a specific embodiment of device 100, nanowire 104 may correspond to a remaining portion of a semiconductor surface layer of a substrate of semiconductor-on-insulator type, for example SOI (Silicon On Insulator). Support layer 102, in this case, may correspond to the stack comprising the buried dielectric layer arranged on the solid semiconductor layer of the semiconductor-on-insulator substrate. The buried dielectric layer corresponds, for example, to an SiO₂ layer and the solid layer comprises, for example, silicon.

For example, nanowire 104 may comprise silicon when the qubits intended to be used in device 100 correspond to electron or hole qubits. As a variant, nanowire 104 may for example comprise germanium when the qubits intended to be used in device 100 correspond to hole qubits.

In this first example as well as in the next examples of embodiment, a width W of nanowire 104 (dimension parallel to the Y axis shown in FIGS. 1 and 2) is, for example, in the range from 15 nm to 120 nm, or from 30 nm to 120 nm. A thickness H of nanowire 104 (dimension parallel to the Z axis shown in FIGS. 1 and 2) is, for example, in the range from 5 nm to 20 nm. Finally, a length L of nanowire 104 (dimension parallel to the X axis shown in FIGS. 1 and 2) is a function of the number of quantum dots intended to be formed in nanowire 104, and is for example in the range from 30 nm to 100 nm per qubit.

In this first example, as well as in some of the next examples of embodiment, device 100 comprises at least two separate first control gates 106, arranged next to each other, each covering a portion of a first lateral surface 108 of nanowire 104 (surface parallel to the (X,Z) plane in FIGS. 1 and 2), of an upper surface 112 of nanowire 104 (surface parallel to the (X,Y) plane in FIGS. 1 and 2), and of a first upper edge 110 of nanowire 104 formed at the junction of the first lateral surface 108 and of upper surface 112. The first gates 106 are here configured to each control the electrostatic potential of one of the quantum dots 114 intended to be formed in nanowire 104. Each of the first gates 106 comprises at least one electrically-conductive portion. A portion of of each first gate 106 rests on support layer 102, and another portion of each first gate 106 rests on a portion of a dielectric layer 115 on nanowire 104.

In this first example as well as in the subsequent examples of embodiment, device 100 comprises four first gates 106. As a variant, device 100 may however comprise a different number of first gates 106, this number depending on the number of quantum dots 114 intended to be formed in nanowire 104.

In a specific configuration applicable to the different described examples of embodiment of device 100, each of the first gates 106 may comprise at least one electrically-conductive material such as polysilicon, or a stack of a plurality of materials such as a stack of TiN, polysilicon, and silicide.

In FIGS. 1 and 2, the quantum dots 114 intended to be formed in nanowire 104 are symbolically represented. These quantum dots 114 are intended to be formed in portions of nanowire 104 subject to the electrostatic control of the first gates 106, this electrostatic control being obtained via the electric potential applied to each of these first gates 106.

In a specific configuration applicable to the different examples of embodiment of device 100, each of the first gates 106 has a length L_{G} (dimension parallel to the length L of nanowire 104) for example in the range from 20 nm to 60 nm, and a height H_{G} (dimension parallel to the height H of nanowire 104) for example in the range from 20 nm to 60 nm. The height H_{G} of the first gates 106 depends in particular on the material(s) used to form these first gates 106. Further, two adjacent first gates 106 are spaced apart from each other by a distance S_{G} (parallel to the length L_{G} of each of the first gates 106) for example in the range from 20 nm to 100 nm. Finally, the portion of each of the first gates 106 arranged on the upper surface 112 of nanowire 104 extends over a dimension R_{G}, perpendicular to length L_{G}, for example in the range from 0.2*W to W.

In a specific configuration that may correspond to that shown in FIGS. 1 and 2, the portions of upper surface 112 covered with the first gates 106 may extend from the first upper edge 110 to half the distance separating the first and second lateral surfaces 108, 118 from each other. In other words, in this specific configuration, R_{G}=W/2.

In the first example as well as in the subsequent examples of embodiments of device 100, nanowire 104 is covered with a dielectric layer 115 intended in particular to be used as a gate oxide for the first gates 106. Dielectric layer 115 comprises, for example, SiO₂ and/or Al₂O₃. The thickness of dielectric layer 115 is, for example, in the range from 2 nm to 20 nm. In FIG. 1, dielectric layer 115 is not shown so that nanowire 104 can be visible.

In this first example as well as in the next examples of embodiment, device 100 comprises at least one second control gate 116 covering a portion of a second lateral surface 118, opposite to the first lateral surface 108, of nanowire 104, and configured to control the electrostatic potential of a coupling region intended to be formed between two quantum dots 114. In the example of FIG. 1, the control of the electrostatic potential of a coupling region intended to be formed between two quantum dots 114, by one of the second gates 116, is symbolically represented by an arrow.

In the rest of the disclosure, reference is made to a plurality of second control gates 116 of device 100. However, the various features described in relation with the second control gates 116 would also apply to the single second control gate 116 of device 100 if device 100 had only one second control gate 116.

In this first example as well as in the next examples of embodiment, device 100 comprises three second gates 116. As a variant, device 100 may comprise a different number of second gates 116, this number depending on the number of coupling regions between quantum dots 114 to be controlled.

In a specific configuration applicable to the different examples of embodiments of device 100, each of the second gates 116 has a length L_{J} (dimension parallel to the length L of nanowire 104) for example in the range from 20 nm to 60 nm, and a height H_{J} (dimension parallel to the height H of nanowire 104) for example in the range from 20 nm to 100 nm. Further, two neighboring second gates 116 are spaced apart by a distance S_{J} (parallel to the length L_{J} of each of the second gates 116) for example in the range from 10 nm to 80 nm.

In the first example of embodiment, each of the second gates 116 has a height H_{J} equal to the height H_{G} of the first gates 106. Thus, an upper surface 119 of each of the first gates 106, parallel to the upper surface 112 of nanowire 104, is arranged in a same plane as an upper surface 121 of each of the second gates 116, also parallel to the upper surface 112 of nanowire 104.

In the first example of embodiment, the second gates 116 do not cover portions of the upper surface 112 of nanowire 104. Further, in the described example, dielectric layer 115 also forms the gate oxide for the second gates 116.

In this first example of embodiment, for each of the second gates 116, at least a portion of an orthogonal projection, on the first lateral surface 108, of the portion of the second lateral surface 118 covered with the second gate 116 is arranged between the portions of the first lateral surface 108 covered with two neighboring first gates 106. In a specific configuration such as shown in FIGS. 1 and 2, the edges of the second gate 116 may be aligned with those of the two first gates 106, which signifies that there is no overlap between the orthogonal projection, on the first lateral surface 108, of the portion of the second lateral surface 118 covered with each of the second gates 116 and the portions of the first lateral surface 108 covered with the two first gates 106 arranged on either side of this second gate 116. As a variant, it is possible to have such a partial overlap, for example such that at most half the area of the orthogonal projection, on the first lateral surface 108, of the portion of the second lateral surface 118 covered with each of the second gates 116 covers the portions of the first lateral surface 108 covered with the two first gates 106 arranged on either side of this second gate 116.

A specific configuration of electronic device 100 according to the first example is described hereafter in relation with FIG. 3, which is a side cross-section view of device 100.

The device 100 according to this specific configuration comprises all the elements of the device 100 according to the previously-described first example.

However, in this specific configuration, the portions of upper surface 112 covered with the first gates 106 extend from the first upper edge 110 to a second upper edge 120 of nanowire 104 formed at the junction of the second lateral surface 118 and of upper surface 112. Thus, in this specific configuration, R_{G}=W.

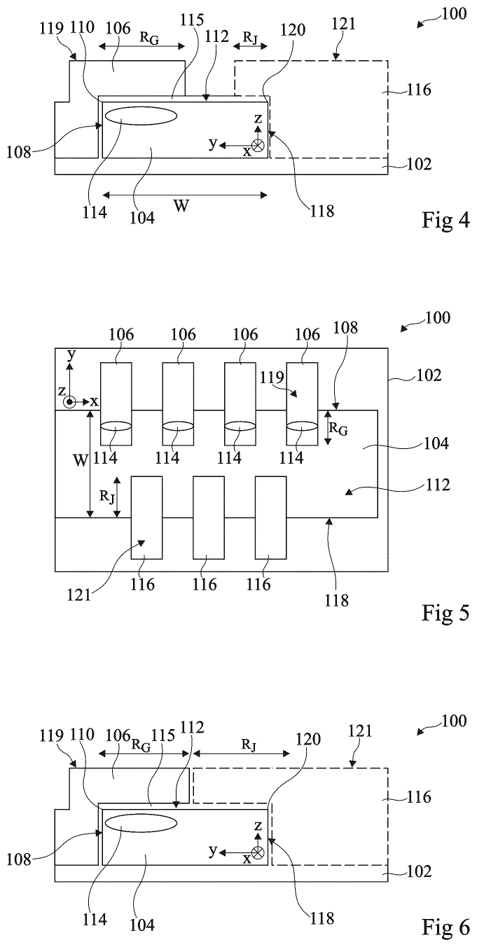

A second example of an electronic device 100 according to a specific embodiment is described hereafter in relation with FIGS. 4 and 5. FIG. 4 is a side cross-section view of device 100 and FIG. 5 is a top view of device 100.

The device 100 according to this second example comprises all the elements of the device 100 according to the previously-described first example.

However, in this second example, each of the second control gates 116 further covers a portion of the second upper edge 120 of nanowire 104, and a portion of the upper surface 112 of nanowire 104.

In this second example, the portion of each of the second gates 116 arranged on the upper surface 112 of nanowire 104 may extend over a dimension R_{J}, perpendicular to length L_{J}, for example in the range from 0 to W/2, or more generally such that R_{G}+R_{J}<W.

In a specific configuration of this second example, the portions of upper surface 112 covered with the second gates 116 may extend from the second upper edge 120 to half the distance separating the first and second lateral surfaces 108, 118 from each other. In other words, in this specific configuration, R_{J}=W/2. Such a specific configuration is shown in FIG. 6.

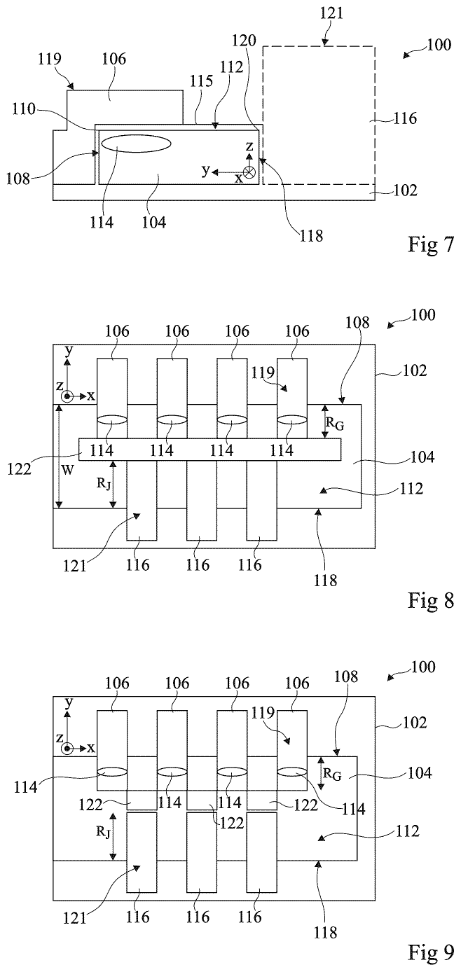

A third example of an electronic device 100 according to a specific embodiment is described hereafter in relation with FIG. 7 corresponding to a side cross-section view of device 100.

The device 100 according to this third example comprises all the elements of the device 100 according to the previously-described first and second examples. Further, as in the first previously-described example, the second gates 116 do not cover portions of the upper surface 112 of nanowire 104.

However, conversely to the previous examples in which each of the second gates 116 has a height H_{J} equal to the height H_{G} of the first gates 106, the height H_{J} of each of the second gates 116 of the device 100 according to this third example is greater than the height H_{G} of the first gates 106. As an example, the value of ratio H/H_{JG} may for example be in the range from 1 to 3. In this third example, the upper surface 119 of each of the first gates 106 is arranged in a first plane located between a second plane in which is arranged the upper surface 121 of each of the second gates 116 and a third plane in which is arranged the upper surface 112 of nanowire 104. This configuration, in which the height H_{J} of the second gates 116 is greater than the height H_{G} of the first gates 106, even further improves the electrostatic control of the coupling regions between quantum dots 114 by the second gates 116.

This feature according to which each of the second gates 116 has a height H_{J} greater than the height H_{G} of the first gates 106 can be applied to the previously-described examples of device 100. In other words, it is possible to have second gates 116 with a height H_{J} greater than the height H_{G} of the first gates 106 and which also cover a portion of the upper surface 112 of nanowire 104 (with, thus, R_{J}>0).

A fourth example of an electronic device 100 according to a specific embodiment is described hereafter in relation with FIG. 8, which is a top view of device 100.

The device 100 according to this fourth example comprises all the elements of the device 100 according to the previously-described third example.

The device 100 according to this fourth example further comprises a dielectric portion 122 running through nanowire 104 from upper surface 112 to a lower surface of nanowire 104 opposite to upper surface 112. The thickness of dielectric portion 122 (dimension parallel to the Z axis) is thus at least equal to the thickness H of nanowire 104.

Dielectric portion 122 is arranged between the portions of the upper surface 112 of nanowire 104 covered with the first gates 106 and the portions of the upper surface 112 of nanowire 104 covered with the second gates 116.

The length of portion 122 (dimension parallel to the length L of nanowire 104) is, for example, such that each of the first gates 106 is arranged in front of portion 122. The width of portion 122 (dimension parallel to the width W of nanowire 104) is, for example, equal to W−R_{G}−R_{J}, as is the case in FIG. 8. As a variant, it is possible for the width of portion 122 to be smaller than W−R_{G}−R_{J}.

In this fourth example, it is possible for each of the second gates 116 to have a height H_{J} greater than or equal to the height H_{G} of the first gates 106.

A fifth example of an electronic device 100 according to a specific embodiment is described hereafter in relation with FIG. 9, which is a top view of device 100.

The device 100 according to this fifth example comprises all the elements of the device 100 according to the previously-described fourth example. However, as compared with the device 100 according to the previously-described fourth example, the device 100 according to this fifth example comprises a plurality of distinct dielectric portions 122 separate from one another. Each of dielectric portions 122 runs through nanowire 104 from upper surface 112 to the lower surface of nanowire 104. The thickness of each of dielectric portions 122 (dimension parallel to the Z axis) is thus equal to the thickness H of nanowire 104.

In this fifth example, each of dielectric portions 122 is arranged between a portion of the upper surface 112 of nanowire 104 arranged between the portions of the upper surface 112 of nanowire 104 covered with the first gates 106 and the portion of the upper surface 112 of nanowire 104 covered with one of the second gates 116.

The length of each of the portions 122 (dimension parallel to the length L of nanowire 104) is, for example, greater than or equal to the length L_{G} of each of the second gates 116 (equal in the example of FIG. 9). The width of each of portions 122 (dimension parallel to the width W of nanowire 104) is, for example, equal to W−R_{G}−R_{J}. As a variant, it is possible for the width of each of portions 122 to be smaller than W−R_{G}−R_{J}.

In this fifth example, it is possible for each of the second gates 116 to have a height H_{J} greater than or equal to the height H_{G} of the first gates 106.

In the different examples of embodiment of device 100, an electric potential may be applied to the first gates 106 to create quantum dots 114 in nanowire 104. The second gates 116 are used to couple or decouple the qubits from quantum dots 114 according to needs, by applying thereto adapted electric potentials.

In all the previously-described examples of embodiment of device 100, the overlap of the first gates 106 on the upper surface 112 of nanowire 104 strongly limits the impact of the second gates 116 on electrostatic phenomena occurring in the regions of nanowire 104 where quantum dots 114 are formed.

In all the examples of embodiment of device 100, the second gates 116 intended to ensure the control of the tunnel coupling between quantum dots 114 are formed at the same level, with a height H_{J} greater than or equal to the height H_{G} of the first gates 106, as the first gates 106 intended to ensure the forming of quantum dots 114 in nanowire 104, and aligned in front of the spaces located between the first gates 106.

In the different previously-described examples of embodiment of device 100, for each of the second gates 116, at least a portion of an orthogonal projection, on the first lateral surface 108, of the portion of the second lateral surface 118 covered with the second gate 116 is arranged between the portions of the first lateral surface 108 covered with two adjacent first gates 106. This arrangement of the second gates 116 relative to the first gates 106 enables to obtain a strong electrostatic control of the tunnel coupling between quantum dots 114, while avoiding the forming of unwanted quantum dots under the second gates 116.

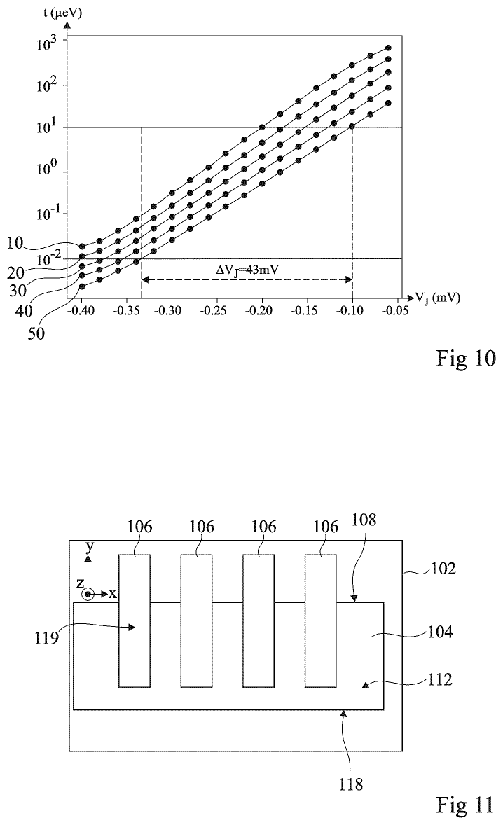

The curves shown in FIG. 10 show the variation of the tunnel coupling t, expressed in μeV, obtained in a device 100 by varying the voltage V_{J}, expressed in mV and corresponding to DC voltage pulses, applied to the second gates 116 of device 100, and for different values of the voltage V_{G}, expressed in mV, applied to the first gates 106 of device 100 forming the quantum dots 114 in which electrons or holes are trapped and the tunnel coupling of which is controlled. The curves designated with references 10, 20, 30, 40, and 50 respectively show the tunnel coupling t obtained for values of voltage V_{G} respectively equal to 50 mV, 75 mV, 100 mV, 125 mV, and 150 mV and for a variation of V_{J} between −0.4 mV and −0.05 mV.

These simulations show that in device 100, the tunnel coupling between two quantum dots 114 can change from an open state (t>10¹ μeV) to a closed state (t<10⁻² μeV), or vice versa, with a variation of the voltage V_{J} applied to the second gates 116 in the order of 43 mV.

The control, called α, of tunnel coupling t can be expressed by the equation:

[Math 1]

$$α = \frac{δ {log}^{2} ( t )}{δ {V}_{J}}$$

With device 100, the obtained control α of tunnel coupling t is in the order of 900 V⁻¹. As a comparison, the control of the tunnel coupling obtained with devices of prior art is generally lower than approximately 40 V⁻¹.

In the different previously-described examples, the edges of each of the second gates 116 are aligned with those of two neighboring first gates 106, which implies that L_{G}=S_{J} and L_{J}=S_{G}. As a variant, it is possible to have an overlap between the orthogonal projection, on the first lateral surface 108, of the portion of the second lateral surface 118 covered with the second gate 116 and the portions of the first lateral surface 108 covered with the two adjacent first gates 106. In this case, dimensions L_{G}, S_{G}, L_{J}, and S_{J} are such that L_{J}>S_{G} and L_{G}>S_{J}.

In all the examples of embodiment, it is possible to have L_{G}>S_{G} and L_{J}>S_{J}, which enables to decrease the gate pitch achievable with device 100.

In all the examples of embodiment, it is also possible to have second gates 116 longer than the first gates 106, that is, such that L_{J}>L_{G}, or shorter than the first gates 106, that is, such that L_{J}<L_{G}. Similarly, dimension S_{G} may be greater than or smaller than or equal to dimension S_{J}.

In all the examples of embodiment, it is possible to size and position the first and second gates 106, 116 such that L_{G}+S_{G}=L_{J}+S_{J}.

In all the examples of embodiment, the first and second gates 106, 116 may be sized in such a way that R_{G}+R_{J}<W in order to avoid problems of undesired electrical contact between the first and second gates 106, 116.

Device 100 may comprise a gate structure 106, 116 compatible with manufacturing processes of the microelectronics industry and which enables to have a strong electrostatic control of the tunnel coupling between quantum dots 114. The first gates 106 used for the forming of the quantum dots 114 and the second gates 116 used for the control of the tunnel coupling between quantum dots 114 are arranged in a same gate level, which facilitates their implementation.

Device 100 comprises at least two first gates 106, the number of first gates 106, and thus also of second gates 116, being selected according to the number of quantum dots 114 to be formed and to be controlled in nanowire 104.

A first example of a method of forming electronic device 100 is described hereafter in relation with FIGS. 11 to 13.

Nanowire 104 is first formed, for example by etching of the surface layer of an SOI substrate. Other techniques may be used to form nanowire 104 on support layer 102.

Dielectric layer 115 is then formed in such a way as to cover nanowire 104. For example, when dielectric layer 115 comprises SiO₂ and nanowire 104 comprises silicon, dielectric layer 115 may be formed by thermal oxidation of the silicon of nanowire 104.

The first gates 106 are then formed, for example by lift-off type deposition of one or a plurality of electrically-conductive materials. The structure obtained at this stage of the method is shown in FIG. 11.

The second gates 116 are then formed, for example by lift-off type deposition of one or a plurality of electrically-conductive materials. The structure obtained at this stage of the method is shown in FIG. 12.

A step of etching of the first and second gates 106, 116 is then implemented in order to obtain the dimensions desired for these gates 106, 116, in particular the desired dimensions R_{G} and R_{J}. The device 100 thus obtained is shown in FIG. 13.

As a variant of the above-described method, it is possible for the first and second gates 106, 116 to be formed by implementing a same deposition step.

A second example of a method of forming an electronic device 100 is described hereafter.

Nanowire 104 and dielectric layer 115 are first formed, for example as previously described for the first example of a method of forming device 100.

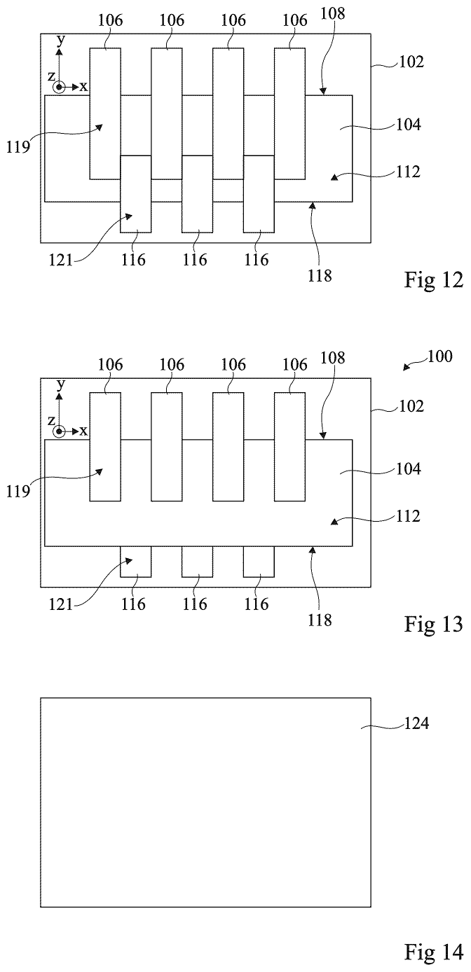

One or a plurality of layers 124 of electrically-conductive material are then deposited over the entire structure, that is, over nanowire 104 covered with dielectric layer 115 and on the portions of support layer 102 not covered with nanowire 104 and dielectric layer 115. FIG. 14 shows a top view of the structure obtained at this stage of the method.

Layer(s) 124 are then etched by using a hard mask, forming the first gates 106 and the second gates 116 either during a same etch step or during separate etch steps. The structure obtained at this stage of the method is similar to that shown in FIG. 12.

A step of etching of the first and second gates 106, 116 is then implemented in order to obtain the dimensions desired for these gates 106, 116, in particular the desired dimensions R_{G} and R_{J}. The device 100 thus obtained is similar to that shown in FIG. 13.

As a variant of the above-described methods, it is possible to form the first and second gates 106, 116 directly to the desired dimensions, without having to implement the final etch step described in relation with FIG. 13.

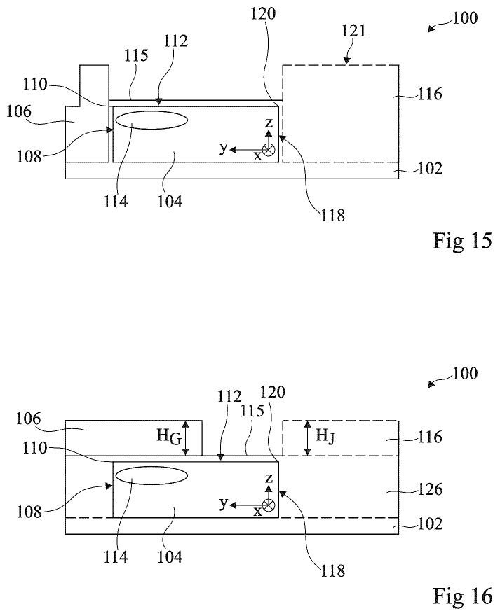

FIG. 15 shows a fifth example of embodiment of device 100.

In this fifth example, conversely to the previous examples of embodiment, neither the first gates 106 nor the second gates 116 cover the upper surface 112 of nanowire 104, nor the upper edges 110, 120 of nanowire 104. Further, each of the first gates 106 covers a portion of the first lateral surface 108 of nanowire 104, and each of the second gates 116 covers a portion of the second lateral surface 118 of nanowire 104. In this fifth example, the following relation is verified: R_{G}=R_{J}=0. The other features and variants previously described for the previous examples of embodiment, such as for example the fact of having first gates 106 of a height different from that of the second gates 116 (H_{J}≠H_{G}) can be applied to this fifth embodiment.

FIG. 16 shows a sixth example of embodiment of device 100.

In this sixth example, conversely to the previous examples of embodiment, neither the first gates 106 nor the second gates 116 cover portions of the first and second lateral surfaces 108, 118 of nanowire 104. Further, each of the first gates 106 covers a portion of the upper surface 112 of nanowire 104. The second gates 116 do not cover the upper surface 112 of nanowire 104. In this sixth example, dimension R_{G} is non-zero, and dimension R_{J} is zero. As a variant, it is possible for the second gates 116 to cover a portion of the upper surface 112 of nanowire 104, so that R_{J}>0, and/or for the heights H_{G} and H_{J} of the first and second gates 106, 116 to be different.

In this sixth example, the first and second gates 106, 116 do not rest directly on the support layer, but on at least one dielectric material 126 interposed between support layer 102 and the first and second gates 106, 116. Dielectric material 126 may, for example, be used to also form dielectric layer 115.

In this sixth example, the first and second gates 106, 116 form planar gates.

In all the examples of embodiment, the first control gates 106 are arranged on the side of the first lateral surface 108 of nanowire 104, and the second control gates 116 are arranged on the side of the second lateral surface 118 of nanowire 104.

In the different described examples of embodiment, it is possible for no portion of the second gate 116 to be arranged, physically or in projection, for example in a plane parallel to the first lateral surface 108, between the two first gates 106.

In the different examples of embodiment, at least a portion of an orthogonal projection of the or of each of the second control gates 116 in a plane perpendicular to the upper surface 112 of nanowire 104, or in a plane parallel to lateral surfaces 108, 118, may be arranged between orthogonal projections of two first control gates 106 in the plane perpendicular to upper surface 112 or in the plane parallel to lateral surfaces 108, 118.

In the different examples of embodiment, the first control gates 106 may be arranged in the same plane as the second control gate(s) 116.

In the different previously-described examples of embodiment, except for that described in relation with FIG. 8, when R_{J} is non-zero, that is, when the second gates 116 cover portions of the upper surface 112 of nanowire 104, the second gates 116 may be used to perform, in addition to the control of the coupling regions between quantum dots 114, a spin readout based on Pauli blockade (Elzerman-type readout). In this case, the spin readout is performed by quantum dots formed under the second gates 116.

To avoid the triggering of undesired charge transfers with the qubits, and when dimension R_{J} is non-zero, device 100 may preferably be formed in such a way that it comprises one or a plurality of dielectric portions 122 such as previously described in relation with FIGS. 8 and 9, since this or these dielectric portions 122 then prevent such charge transfers. The second gates 116 may in this case be used as charge detectors by means of quantum dots formed under the second gates 116.

As an variant of a reading of the qubits with the second gates 116, the qubits of quantum dots 100 may be read by using auxiliary quantum dots formed in the vicinity of lateral surfaces of nanowire 104 which are, for example, perpendicular to lateral surfaces 108, 118. For example, considering the device 100 shown in FIG. 1, these auxiliary quantum dots may correspond to those formed under each of the two first gates 106 closest to the ends of nanowire 104.

As a variant of the different previously-described examples of embodiments, it is possible for nanowire 104 not to correspond to a remaining portion of a surface layer of a semiconductor-on-insulator substrate, and to be formed, for example by deposition or any other suitable technique, on or from another type of support layer 102 corresponding, for example, to a bulk or solid substrate such as a semiconductor wafer.

As a variant of the different previously-described examples of embodiments, the gate oxides arranged between nanowire 104 and the first gates 106 and/or the second gates 116 may be formed by portions of dielectric material different from dielectric layer 115.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove. For example, the nature (wet, dry, etc.) of each of the implemented etchings may be selected according, in particular, to the material(s) to be etched.

1. Electronic device comprising:
a semiconductor nanowire;
at least two separate first control gates, arranged next to each other on the side of a first lateral surface of the semiconductor nanowire, and configured to each control the electrostatic potential of a quantum dot intended to be formed in the semiconductor nanowire;
at least one second control gate arranged on the side of a second lateral surface, opposite to the first lateral surface, of the semiconductor nanowire, and configured to control the electrostatic potential of a coupling region intended to be formed between two quantum dots;
wherein all the first control gates of the electronic device are arranged on the side of the first lateral surface only, and the or all the second control gates of the electronic device are arranged on the side of the second lateral surface only,
and wherein no portion of the second gate is arranged between the first gates (106).

2. Electronic device according to claim 1, wherein at least a portion of an orthogonal projection of the second control gate in a plane parallel to the first lateral surface of the semiconductor nanowire is arranged between orthogonal projections of the two first control gates in the plane parallel to the first lateral surface of the semiconductor nanowire.

3. Electronic device according to claim 1, wherein each of the first control gates covers a portion of the first lateral surface of the semiconductor nanowire, or wherein the second control gate covers a portion of the second lateral surface of the semiconductor nanowire.

4. Electronic device according to claim 1, wherein the second control gate covers a portion of the second lateral surface of the semiconductor nanowire.

5. Electronic device according to claim 1, wherein each of the first control gates covers a portion of an upper surface of the semiconductor nanowire which is perpendicular to the first and second lateral surfaces.

6. Electronic device according to claim 1, wherein the second control gate covers a portion of the upper surface of the semiconductor nanowire.

7. Electronic device according to claim 5, wherein the portions of the upper surface covered with the first control gates extend from a first upper edge of the semiconductor nanowire formed at the junction of the first lateral surface and of the upper surface, to approximately half the distance separating the first and second lateral surfaces from each other.

8. Electronic device according to claim 5, wherein the portions of the upper surface covered with the first control gates extend from a first upper edge of the semiconductor nanowire formed at the junction of the first lateral surface and of the upper surface to a second upper edge of the semiconductor nanowire formed at the junction of the second lateral surface and of the upper surface.

9. Electronic device according to claim 6, wherein the portion of the upper surface covered with the second control gate extends from a second upper edge of the semiconductor nanowire formed at the junction of the second lateral surface and of the upper surface to approximately half the distance separating the first and second lateral surfaces from each other.

10. Electronic device according to claim 5, wherein the second control gate covers a portion of the upper surface of the semiconductor nanowire, and further comprising a dielectric portion running through the semiconductor nanowire from the upper surface of the semiconductor nanowire to a lower surface of the semiconductor nanowire opposite to the upper surface and arranged:
between the portions of the upper surface of the semiconductor nanowire covered with the first control gates and the portion of the upper surface of the semiconductor nanowire covered with the second control gate, or
between a portion of the upper surface of the semiconductor nanowire located between the portions of the upper surface of the semiconductor nanowire covered with the first control gates and the portion of the upper surface of the semiconductor nanowire covered with the second control gate.

11. Electronic device according to claim 1, wherein:
an upper surface of the second control gate, parallel to the upper surface of the semiconductor nanowire, is arranged in a same first plane as an upper surface of each of the first control gates, or
the upper surface of each of the first control gates is arranged in a first plane located between a second plane in which is arranged the upper surface of the second control gate and a third plane in which is arranged an upper surface of the semiconductor nanowire, which is perpendicular to the first and second lateral surfaces.

12. Electronic device according to claim 1, wherein said at least one second control gate has a dimension, measured along an extension direction of the semiconductor nanowire, smaller than a sum of the dimensions of each of the two first control gates along the extension direction of the semiconductor nanowire.

13. Electronic device according to claim 1, comprising N first control gates and N+1 second control gates, with N an integer greater than or equal to 2.

14. Electronic device according to claim 1, wherein a distance between said at least one second control gate and the semiconductor nanowire is shorter than 20 nm, and preferably shorter than 10 nm.

15. Method of forming an electronic device, comprising:
forming of at least two separate first control gates, arranged next to each other on the side of a first lateral surface of a semiconductor nanowire, and configured to each control the electrostatic potential of at least one quantum dot intended to be formed in the semiconductor nanowire;
forming of at least one second control gate arranged on the side of a second lateral surface, opposite to the first lateral surface, of the semiconductor nanowire, and configured to control the electrostatic potential of a coupling region intended to be formed between two quantum dots;
wherein all the first control gates of the electronic device are arranged on the side of the first lateral surface only, and the or all the second control gates of the electronic device are arranged on the side of the second lateral surface only,
and wherein no portion of the second gate is arranged between the first gates.

16. Method according to claim 15, wherein the first and second control gates are formed by the implementation:
of at least one lift-off type deposition of at least one electrically-conductive material, or
of at least one deposition of at least one layer of electrically-conductive material on a substrate including the semiconductor nanowire, followed by at least one etching of the layer of electrically-conductive material through openings made in a mask.

17. Method according to claim 16, further comprising, after the lift-off type deposition of the electrically-conductive material or after the etching of the layer of electrically-conductive material, the implementation of an additional etching of remaining portions of the electrically-conductive material or of the layer of electrically-conductive material, completing the forming of the first and second control gates.

18. Method according to claim 15, wherein the forming of the first and second control gates is implemented in such a way that at least a portion of an orthogonal projection of the second control gate in a plane parallel to the first lateral surface of the semiconductor nanowire is arranged between orthogonal projections of the two first control gates in the plane parallel to the first lateral surface of the semiconductor nanowire.
